(19) United States
(12) Patent Application Publication
(10) Pub. No.: US 2026/0234801 A1
(43) Pub. Date: Aug. 13, 2026

(54) LOAD-LOCK APPARATUS

(71) Applicant: NISSIN ION EQUIPMENT CO., LTD., Koka-city (JP)

(72) Inventors: Koyu UENO, Koka-city (JP); Masatoshi ONODA, Koka-city (JP)

(73) Assignee: NISSIN ION EQUIPMENT CO., LTD., Koka-city (JP)

(21) Appl. No.: 19/448,845

(22) Filed: Jan. 14, 2026

(30) Foreign Application Priority Data
Feb. 7, 2025 (JP) 2025-018859

(51) Int. Cl. C23C 16/46; C23C 16/52

(52) U.S. Cl. CPC C23C 16/46; C23C 16/52

(57) ABSTRACT

A load-lock apparatus includes a fixed part and a movable part that forms a load-lock chamber by connecting with the fixed part and that is movable in a vacuum. The movable part includes a heat source and a support member. The support member partially supports a rear surface of a substrate at a position spatially separated from the heat source.

### CROSS REFERENCE TO RELATED APPLICATION

This application is based on and claims priority from Japanese Patent Application No. JP 2025-18859 filed on Feb. 7, 2025 in the Japan Patent Office, the contents of which being incorporated by reference herein in its entirety.

### BACKGROUND

### Field

The present disclosure relates to a load-lock apparatus configured to preliminarily heat a substrate.

### Description of Related Art

In certain apparatuses, such as chemical vapor deposition apparatuses and some ion implanters, a substrate is heated to a predetermined high temperature before being processed in a process chamber.

As an example, when a target temperature of the substrate is high and it is necessary to avoid rapid thermal deformation, the substrate may be preheated to a predetermined temperature. After preheating, the substrate is transferred to the process chamber and further heated to the final temperature.

### SUMMARY

According to an aspect of one or more embodiments, a load-lock apparatus may comprise:

a fixed part; and

a movable part that forms a load-lock chamber by connecting with the fixed part and that is movable in a vacuum,

wherein the movable part comprises a heat source and a support member, the support member being configured to partially support a rear surface of a substrate at a position spatially separated from the heat source.

According to another aspect of one or more embodiments, a load-lock apparatus may comprise:

a fixed part; and

a movable part that forms a load-lock chamber by connecting with the fixed part and is movable in a vacuum,

wherein the movable part comprises a heat source and a support member, the support member being configured to partially support a rear surface of a substrate at a position spatially separated from the heat source, and

wherein the load-lock apparatus further comprises a temperature measuring device configured to measure a temperature of the substrate, and a controller configured to control the heat source based on the measured temperature.

### BRIEF DESCRIPTION OF THE DRAWINGS

The above and/or other aspects will become apparent and more readily appreciated from the following description of various embodiments, taken in conjunction with the accompanying drawings, in which:

FIG. 1 illustrates an example configuration of a load-lock apparatus, according to some embodiments;

FIG. 2 illustrates a state in which a movable part of the load-lock apparatus has moved in a -Y axis direction from a state of the load-lock apparatus shown in FIG. 1, according to some embodiments;

FIG. 3 illustrates an example configuration of a support member of the load-lock apparatus shown in FIG. 1, according to some embodiments;

FIG. 4 illustrates an example configuration of a heat source of the load-lock apparatus shown in FIG. 1, according to some embodiments;

FIG. 5 illustrates an example configuration of a load-lock apparatus, according to some embodiments;

FIG. 6 illustrates an example configuration of a load-lock apparatus, according to some embodiments;

FIG. 7 illustrates an example configuration of a load-lock apparatus, according to some embodiments;

FIG. 8 illustrates an example configuration of a load-lock apparatus, according to some embodiments; and

FIG. 9 illustrates an example configuration of a load-lock apparatus, according to some embodiments.

### DETAILED DESCRIPTION

The heating of the substrate may be carried out either in an electrostatic chuck that supports the substrate inside the process chamber, in a load-lock chamber provided along a transfer path to the process chamber, or in both locations.

As discussed above, as an example, when the target temperature of the substrate is high and it is necessary to avoid rapid thermal deformation, the substrate may be preheated to the predetermined temperature in the load-lock chamber. After preheating, the substrate may be transferred to the process chamber, where the substrate may be further heated to the final temperature by the electrostatic chuck.

Hereinafter, various embodiments of the present disclosure will be described with reference to the drawings. In all the drawings for explaining the various embodiments, common components are denoted by the same reference numerals, and repeated description thereof will be omitted for conciseness. The following embodiments do not unduly limit the contents of the present disclosure described in the appended claims. Further, all the components shown in the embodiments are not necessarily essential components of the present disclosure. Each drawing is a schematic view and is not necessarily intended to illustrate various dimensions strictly.

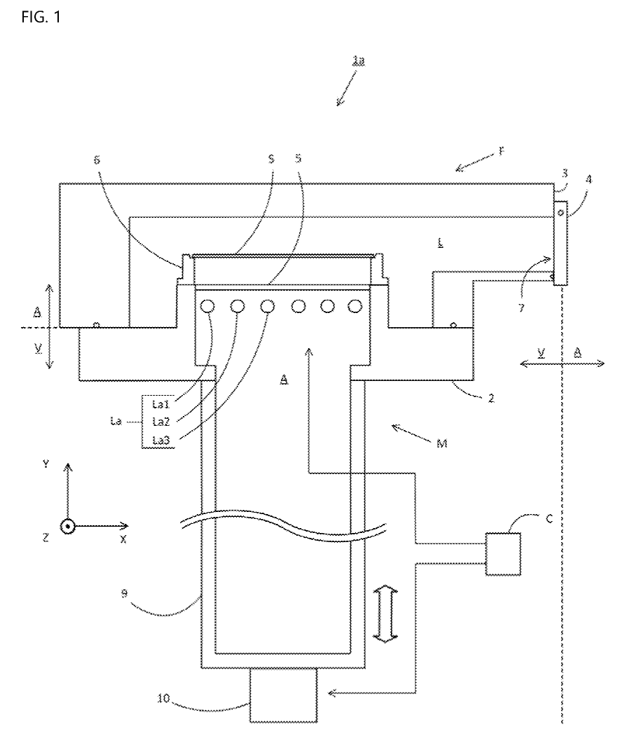

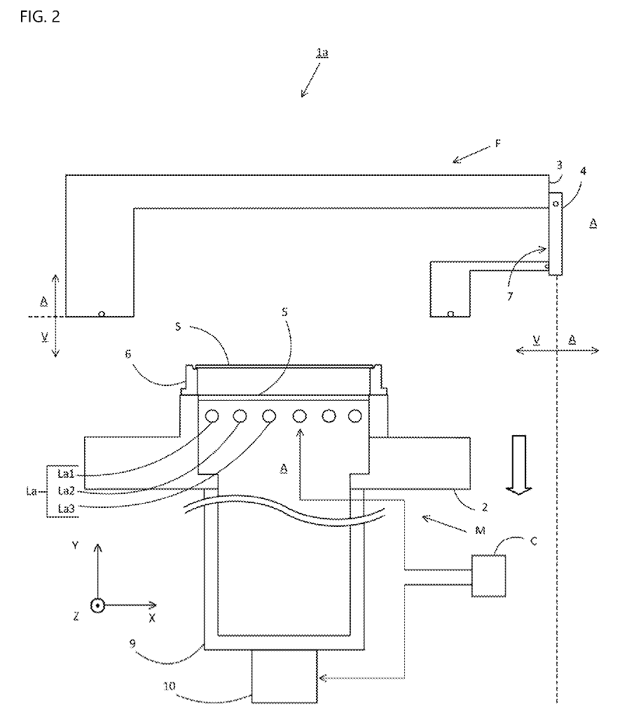

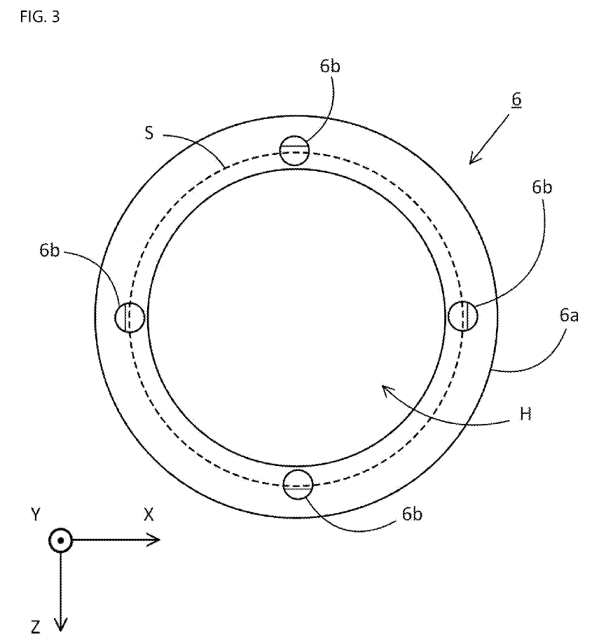

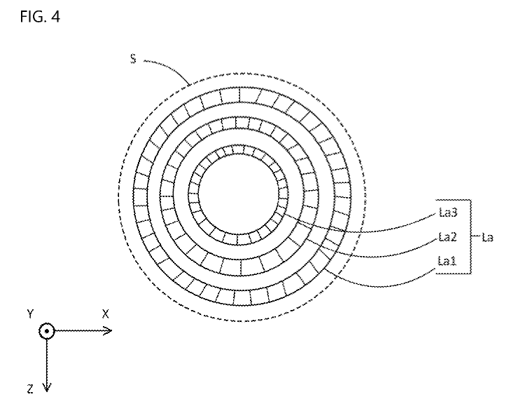

FIG. 1 illustrates an example configuration of a load-lock apparatus, according to some embodiments. FIG. 2 illustrates a state in which a movable part of the load-lock apparatus has moved in a -Y axis direction from a state of the load-lock apparatus shown in FIG. 1, according to some embodiments. FIG. 3 illustrates an example configuration of a support member of the load-lock apparatus shown in FIG. 1, according to some embodiments. FIG. 4 illustrates an example configuration of a heat source of the load-lock apparatus shown in FIG. 1, according to some embodiments.

Referring to FIGS. 1 to 4, an example configuration of a load-lock apparatus 1a is described. As shown in FIG. 1, the load-lock apparatus 1a includes a movable part M (which may include a heat source La and a support member 6, as described below) that moves in a direction parallel to the Y-axis, and a fixed part F whose position remains stationary.

In the figures, the X, Y, and Z axes are mutually orthogonal. The -Y axis direction is opposite to the Y axis and corresponds to the direction of gravity. The -X axis direction is opposite to the X axis. The direction parallel to the Y axis is referred to as the vertical direction, and the direction parallel to the X axis is referred to as the horizontal direction.

In an embodiment, the movable part M moves vertically within a vacuum region V when transferring a substrate S. The connection state between the movable part M and the fixed part F changes as the movable part M moves. In FIG. 1, the movable part M and the fixed part F are shown in a connected state, in which a first base member 2 of the movable part M and a second base member 3 of the fixed part F are in contact, forming a load-lock chamber L. In other words, when the movable part M and the fixed part F are in the connected state, the first base member 2 and the second base member 3 define the load-lock chamber L. When transferring the substrate S between the process chamber (not shown) and the load-lock chamber L, the movable part M and the fixed part F are in a disconnected state, as shown in FIG. 2.

The substrate S may be, for example, a semiconductor substrate such as silicon substrate or silicon carbide substrate. Glass substrates may also be used. A shape of the substrate S is not limited to a circular shape and may be a rectangular shape, or other shape. The number of substrates S is not limited to one, and by modifying the configuration of the support member 6, a plurality of substrates S may be handled.

The fixed part F includes the second base member 3 that forms the ceiling of the load-lock chamber L. At one end of the second base member 3, a loading port 7 is provided as a transfer path for moving the substrate S in a direction parallel to the X axis. The loading port 7 may be opened and closed by rotating a flap valve 4 about the Z axis.

A chamber (not shown) is disposed below the flap valve 4 and the second base member 3. In the configuration shown in FIG. 1, the region on the X axis side of the flap valve 4 is an atmospheric region (A), and the region on the -X axis side is the vacuum region (V). Similarly, the region on the Y axis side of the second base member 3 is the atmospheric region (A), and the region on the -Y axis side is the vacuum region (V). The vacuum region (V) refers to a region where the pressure is lower than that of the atmospheric region (A).

The movable part M includes the support member 6 and the heat source La. The support member 6 supports the substrate S and the heat source La heats the substrate S. FIG. 3 is a plan view of the support member 6 in the XY plane. The support member 6 includes an annular base 6a having a central opening H and a plurality of pins 6b extending in the Y axis direction from the base 6a. The pins 6b partially support the rear surface of the substrate S, as indicated by the dashed line in FIG. 3. The number of pins 6b is not limited to four. The number of pins 6b and the configuration of the pins 6b are not limited to those shown and may be any number of two or more, as long as the substrate S may be stably supported and the rear surface may be partially supported. In some embodiments, the pins 6b may be arranged directly on the first base member 2 instead of on the base 6a.

The heat source La may be, for example, a lamp heater, and as shown in FIG. 4, may include three annular lamps La1, La2, and La3 of different diameters. The three annular lamps La1, La2, and La3 form individual heating regions. On the Y axis side of the location where the heat source La is disposed, a window 5 that transmits thermal radiation from the heat source La is provided. For example, quartz glass or sapphire glass, each of which is excellent in heat resistance and transmittance, may be used for the window 5. The location where the heat source La is disposed is the atmospheric region (A) and is surrounded by the window 5, the first base member 2, and a support shaft 9.

It is advantageous that the support member 6 is also made of quartz glass or sapphire glass, which transmits thermal radiation, similar to the window 5. By using such materials, thermal radiation may be irradiated to the support portion of the substrate S, making it possible to heat the entire rear surface of the substrate S. If the support member 6 is made of a material that transmits thermal radiation, the support member 6 may be arranged on the window 5 instead of on the first base member 2, as shown in FIG. 1. However, in a configuration in which the area of the support portion is very small compared to the area of the substrate S and the influence on heating is negligible, it is not necessary to use a material that transmits thermal radiation for the support member 6.

The first base member 2 is connected to the support shaft 9 that moves the first base member 2 in a direction parallel to the Y axis. The support shaft 9 is moved by a drive structure 10 that includes a drive source such as a motor and a drive mechanism such as a transfer gear. When the drive structure 10 moves the support shaft 9, the first base member 2, the heat source La, and the support member 6 move together.

In an embodiment, the load-lock apparatus 1a may include a controller C. The controller C controls the drive structure 10 to move the movable part M in a predetermined direction when transferring the substrate S between the process chamber and the load-lock chamber L. The controller C may independently control the lamps La1, La2, and La3 such that the heat output from the lamps La1, La2, and La3 heats the substrate S to a predetermined temperature.

The controller C includes a processing unit and a storage. The processing unit may be a microprocessor, a central processing unit, a microcontroller, hardware control logic, or a combination thereof. The processing unit may be provided as a plurality of processing units. The storage may store program code for implementing various functions, such as storing data, performing calculations, and controlling the transfer and heating of the substrate S. The processing unit accesses the program code stored in the storage and executes the program code to execute various functions. The processing unit controls the heat source La so that the measured value of the substrate temperature approaches the target value by comparing the measured substrate temperature with the ideal temperature distribution data stored in the storage.

As described in FIGS. 1 to 4, in some embodiments, a part of a load-lock chamber L is configured as the movable part M that is movable in the vacuum region V, and the support member 6 and the heat source La are arranged in the movable part M. This configuration enables the substrate S to be transferred to the process chamber side while being heated, thereby suppressing a decrease in the substrate temperature during transfer and improving productivity in substrate processing.

In a configuration in which the entire rear surface of the substrate is placed on the support member, thermal radiation from the heat source may not easily reach the substrate S, making it difficult to increase the substrate temperature. In addition, the substrate S may not always be flat, and some distortion or warping may be present within the substrate S. In a configuration in which the entire rear surface of the substrate is placed on the support member, temperature differences may easily occur during heating between areas in contact with the mounting surface and areas not in contact with the mounting surface, making it difficult to equalize the temperature within the substrate surface. Conversely, if the support member 6 partially supports the rear surface of the substrate, it may be easier to increase the substrate temperature and equalize the temperature within the substrate surface.

Furthermore, in a configuration in which the entire rear surface of the substrate is placed on the support member 6, when the substrate S is thermally deformed by heating, there may be concerns that a large amount of particles will be generated between the rear surface of the substrate and the mounting surface, or that significant scratches will occur on the rear surface of the substrate. However, if the support member 6 partially supports the rear surface of the substrate, the contact area between the rear surface of the substrate and the support member 6 is small, so the generation of particles and scratches on the rear surface of the substrate may be reduced.

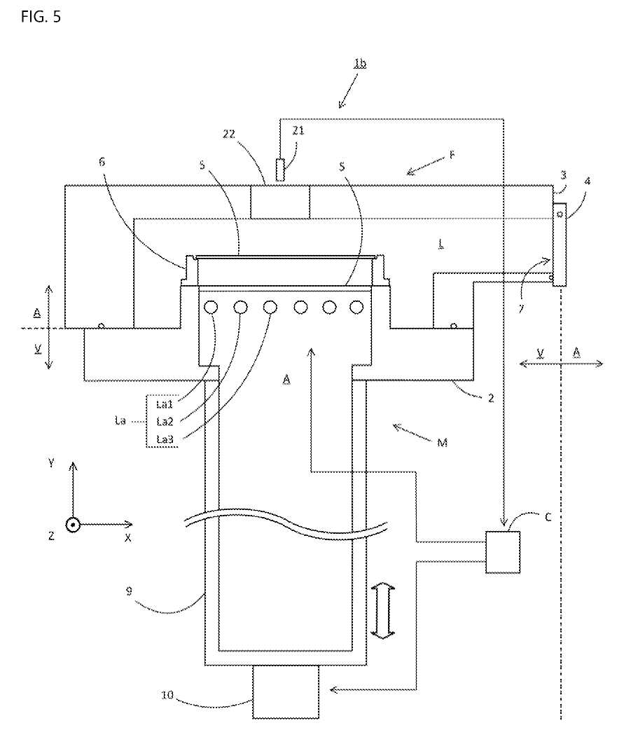

FIG. 5 shows the configuration of a load-lock apparatus 1b, according to some embodiments. The difference from the load-lock apparatus 1a in FIG. 1 is that the load-lock apparatus 1b is provided with a temperature measuring device 21 for measuring the temperature of the substrate during heating. The temperature measuring device 21 may be, for example, a radiation thermometer. In some embodiments, a plurality of radiation thermometers or thermography devices may be arranged to measure the temperature distribution within the substrate S during heating. Such a temperature measuring device 21 is arranged in the atmospheric region A outside the load-lock chamber L. The measurement of the substrate temperature may be performed through a measurement window 22 attached to the second base member 3.

The measurement result from the temperature measuring device 21 is sent to the controller C. The controller C controls the heat source La so that the temperature within the substrate S becomes uniform based on the measurement result.

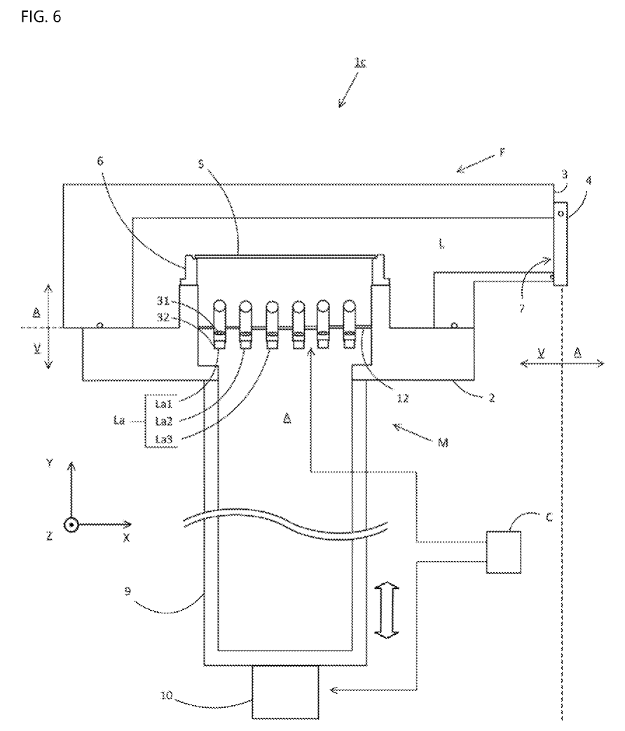

FIG. 6 shows the configuration of a load-lock apparatus 1c, according to some embodiments. The difference from the load-lock apparatus 1a in FIG. 1 is that, in the load-lock apparatus 1c, a part of the heat source La is arranged in the same atmosphere as the load-lock chamber L, and the thermal radiation emitted from the heat source La is directed directly to the rear surface of the substrate S, thereby improving heating efficiency. During heating of the substrate S, the atmosphere in the load-lock chamber L is a vacuum. The heat source La is arranged in the load-lock chamber L except a terminal part of a lamp heater. Each lamp La1–La3 may be, for example, a halogen lamp, and may include a quartz tube filled with an inert gas and a linear tungsten heating element arranged inside the quartz tube.

The quartz tubes of the lamps La1–La3 are attached to a support plate 12. An annular seal member (not shown) is arranged between the quartz tube and the support plate 12. The region on the Y axis side of the support plate 12 has the same atmosphere as the load-lock chamber L, and the region on the -Y axis side is the atmospheric region A. The support plate 12 is made of a refractory metal such as molybdenum or tungsten, which excels in heat resistance and shields thermal radiation emitted from the heat source La. In consideration of deformation due to heat, the support plate 12 has a sufficient thickness for heat capacity. Furthermore, in some embodiments, a coolant flow path may be provided in the first base member 2 to indirectly cool the support plate 12.

The metal member constituting the terminal part of the lamp heater may expand thermally when heated by thermal radiation, causing a gap between the quartz tube and the terminal part 32. In consideration of this expansion, the terminal part 32 is arranged on the atmospheric region A side to suppress heating of the terminal part 32. In some embodiments, a shielding member 31 may be arranged inside the quartz tube to shield thermal radiation emitted from the inside of the quartz tube toward the terminal part 32. The shielding member 31 may be, for example, a metal plate made of a refractory metal such as molybdenum or tungsten.

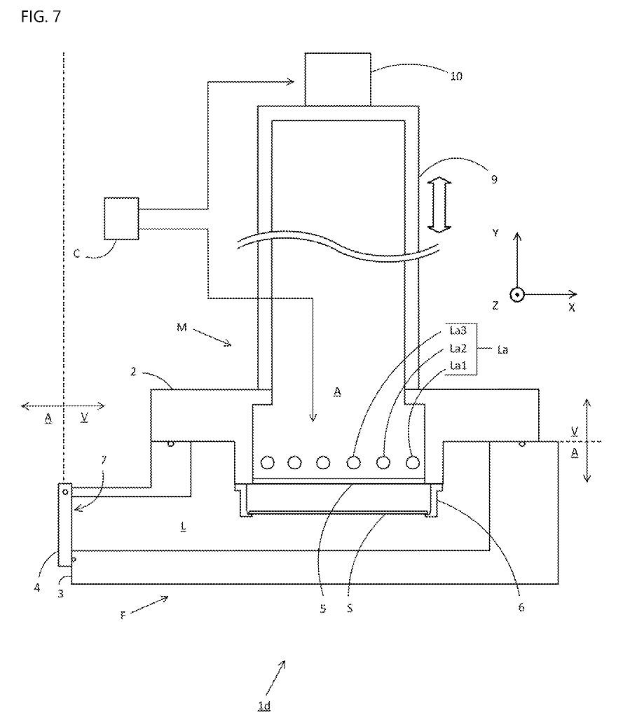

FIG. 7 shows the configuration of a load-lock apparatus 1d, according to some embodiments. The difference from the load-lock apparatus 1a in FIG. 1 is that, in the load-lock apparatus 1d, the moving direction of the movable part M is different. In the load-lock apparatus 1d of FIG. 7, the movable part M moves in the Y axis direction when transferring the substrate S to the process chamber side.

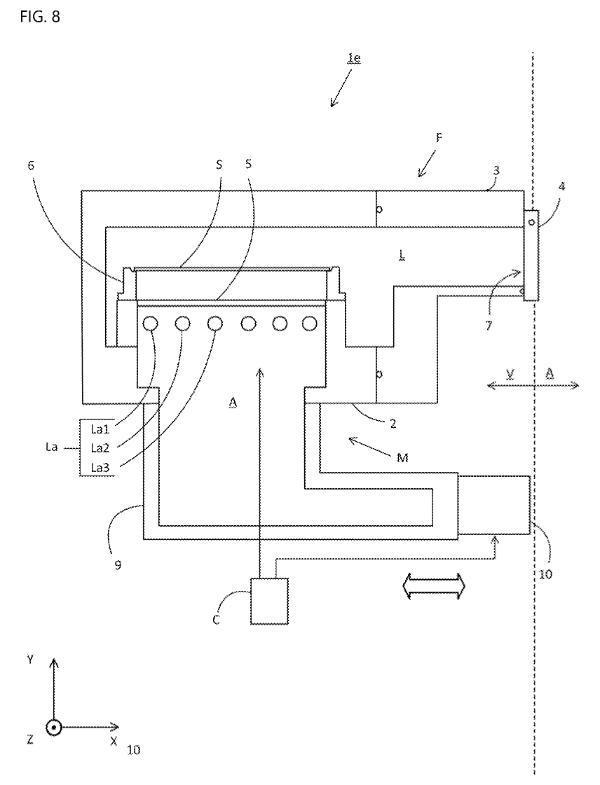

FIG. 8 shows the configuration of a load-lock apparatus 1e, according to some embodiments. The difference from the load-lock apparatus 1a in FIG. 1 is that, in the load-lock apparatus 1e, the moving direction of the movable part M is different. In the load-lock apparatus 1e of FIG. 8, the movable part M moves in the -X axis direction when transferring the substrate S to the process chamber side.

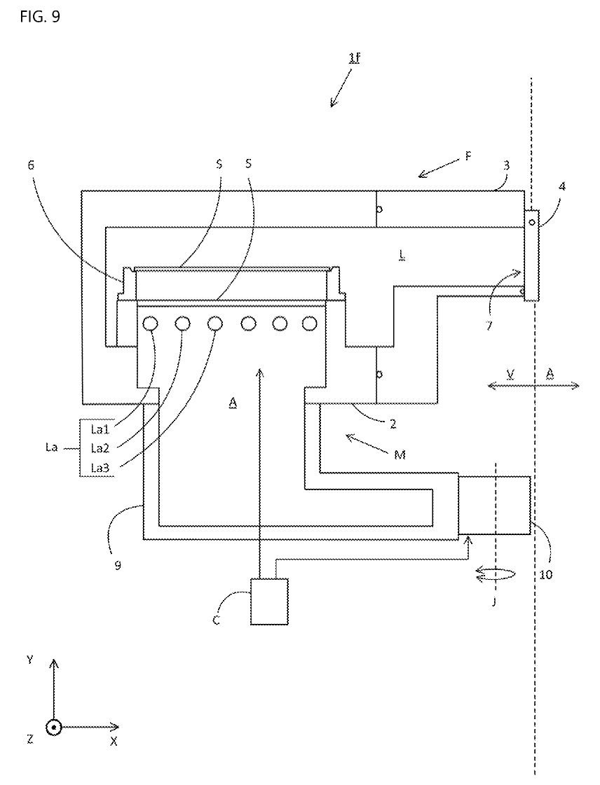

FIG. 9 shows the configuration of a load-lock apparatus 1f, according to some embodiments. The difference from the load-lock apparatus 1a in FIG. 1 is that, in the load-lock apparatus 1f, the moving direction of the movable part M is different. In the load-lock apparatus 1f of FIG. 9, the movable part M rotates about a J axis parallel to the Y axis when transferring the substrate S to the process chamber side.

Even in the configurations described in FIGS. 7 to 9 regarding the moving direction of the movable part M during transfer of the substrate S to the process chamber side, as in the load-lock apparatus 1a described in FIG. 1, it is possible to suppress a decrease in substrate temperature during transfer and improve productivity in substrate processing.

Furthermore, as shown in FIGS. 8 and 9, by moving the movable part M in a direction parallel to the X axis or in the ZX plane, the height of the load-lock apparatus may be kept low. On the other hand, although the height of the load-lock apparatus becomes higher, as in the configuration shown in FIGS. 1 to 7, by moving the movable part M in a direction parallel to the Y axis, it is possible to reduce the footprint of the apparatus on which the load-lock apparatus is mounted.

In the embodiments described so far, an example using a lamp heater as the heat source La has been described, but in some embodiments, a contact-type resistance heating heater may be used instead of the lamp heater. In addition, although the configuration of a halogen lamp has been described as an example of the lamp heater, in some embodiments, other lamp heaters such as LED lamps or flash lamps may be used instead of halogen lamps.

In addition, an example in which the heat source La is divided into heating regions using a plurality of lamps has been described. However, in some embodiments, the heat source La may be configured with a single lamp without providing a plurality of heating regions. The method of dividing the heat source La into a plurality of regions is not limited to the illustrated concentric configuration, and various configurations may be adopted. Furthermore, when the heat source La is configured with a single lamp, unevenness in temperature distribution may occur even if the substrate S is uniformly heated, due to the tendency of distortion in the substrate S. In this case, the density of the linear tungsten arranged in the quartz tube may be changed in advance in consideration of the unevenness in temperature distribution, so that the heating within the substrate surface is performed non-uniformly.

In receiving the substrate S on the support member 6, a vacuum robot may be used. The temperature of the hand of the vacuum robot used for receiving the substrate S is lower than the substrate temperature. Therefore, there may be concerns that the substrate temperature will decrease significantly when the substrate S is received by the hand of the vacuum robot. To suppress such a decrease in substrate temperature, the hand of the vacuum robot may be made of a carbon member that has high heat resistance and does not easily dissipate the heat of the substrate S. In some embodiments, a heater may be built into the hand of the vacuum robot to suppress a decrease in substrate temperature.

In the embodiments described so far, the position of the support member 6 has been fixed. However, the support member 6 may be configured to be movable in a direction parallel to the Y axis so that the distance between the substrate S and the heat source La may be variably adjusted. In some embodiments, instead of making the support member 6 movable, the heat source La may be moved in a direction parallel to the Y axis.

In the embodiments described so far, the support of the substrate S by the support member 6 has been performed at the peripheral edge of the substrate S. However, in some embodiments, the position may be changed as appropriate according to the shape of the robot hand used for transferring the substrate S. For example, in an embodiment, a configuration in which the central vicinity of the rear surface of the substrate S is supported from below may be adopted.

In FIGS. 1 to 9, the first base member 2, the second base member 3, the support shaft 9, and other members are illustrated as being composed of a single member, but the first base member 2, the second base member 3, the support shaft 9, and other members may be composed of a combination of a plurality of members.

The heating of the substrate S by the heat source La may be performed immediately after the flap valve 4 is closed. In some embodiments, the heating may be performed after the atmosphere in the load-lock chamber L becomes a vacuum. In addition, when transferring the substrate S to the process chamber side, heating of the substrate S may be started while moving the movable part M. The heating of the substrate S while moving the movable part M may be performed continuously. In some embodiments, the heating of the substrate S may be performed intermittently according to the movement time or position of the movable part M.

In FIG. 5, an example is illustrated in which the temperature measuring device 21 is arranged in the atmospheric region A outside the load-lock chamber L. However, the arrangement position of the temperature measuring device 21 is not limited to the configuration in FIG. 5, and in some embodiments, the temperature measuring device 21 may be arranged inside the load-lock chamber L. When the temperature measuring device 21 is arranged inside the load-lock chamber L, a thermocouple may be used as the temperature measuring device 21 to directly measure the temperature of the substrate S. Specifically, the thermocouple may be attached to the support member 6 to measure the temperature of the rear surface portion of the substrate S supported by the support member 6.

In some embodiments, when the temperature measuring device 21 is arranged inside the load-lock chamber L, the temperature of the substrate may be measured indirectly instead of directly measuring the substrate temperature using a thermocouple. For example, a metal heat equalizing plate may be arranged between the heat source La and the substrate S, and the temperature of the heat equalizing plate may be measured. In this case, correlation data between the temperature of the substrate S and the temperature of the heat equalizing plate may be obtained in advance by experiment.

The configurations of the load-lock apparatuses 1a–1f shown in FIGS. 1, 5, and 7-9 are merely examples, and are not limited to the configurations shown here, and the configurations shown in each of the load-lock apparatuses 1a–1f may be combined. For example, the load-lock apparatus 1c may be provided with the temperature measuring device 21 or the measurement window 22.

It should be understood that embodiments are not limited to the various embodiments described above, but various other changes and modifications may be made therein without departing from the spirit and scope thereof as set forth in appended claims.

What is claimed is:

1. A load-lock apparatus comprising:
a fixed part; and
a movable part that forms a load-lock chamber by connecting with the fixed part and that is movable in a vacuum,
wherein the movable part comprises a heat source and a support member, the support member being configured to partially support a rear surface of a substrate at a position spatially separated from the heat source.

2. The load-lock apparatus according to claim 1, wherein the heat source is a lamp heater configured to heat the substrate by emitting thermal radiation, and the support member is made of a material that transmits the thermal radiation.

3. The load-lock apparatus according to claim 1, wherein the heat source is a lamp heater configured to heat the substrate by emitting thermal radiation, and a window that transmits the thermal radiation is provided between the heat source and the support member.

4. The load-lock apparatus according to claim 1, wherein the movable part moves in a vertical direction with respect to the fixed part.

5. The load-lock apparatus according to claim 1, further comprising a temperature measuring device configured to measure a temperature distribution of the substrate,
wherein the heat source has a plurality of independently controllable heating regions.

6. The load-lock apparatus according to claim 1, further comprising a controller configured to control the heat source,
wherein the controller controls the output of the heat source to heat the substrate while the movable part is moving.

7. The load-lock apparatus according to claim 1, wherein the support member comprises a plurality of pins extending from an annular base, the plurality of pins being configured to partially support a rear surface of the substrate.

8. The load-lock apparatus according to claim 1, wherein the support member is made of quartz glass or sapphire glass.

9. The load-lock apparatus according to claim 1, wherein the heat source comprises a plurality of annular lamps of different diameters.

10. The load-lock apparatus according to claim 1, further comprising a window made of quartz glass or sapphire glass, the window being disposed between the heat source and the support member.

11. The load-lock apparatus according to claim 1, further comprising a loading port provided at one end of the fixed part, the loading port being openable and closable by a flap valve.

12. A load-lock apparatus comprising:
a fixed part; and
a movable part that forms a load-lock chamber by connecting with the fixed part and that is movable in a vacuum;
wherein the movable part comprises a heat source and a support member, the support member being configured to partially support a rear surface of a substrate at a position spatially separated from the heat source, and
wherein the load-lock apparatus further comprises a temperature measuring device configured to measure a temperature of the substrate, and a controller configured to control the heat source based on the measured temperature.

13. The load-lock apparatus according to claim 12, wherein the temperature measuring device is a radiation thermometer configured to measure a temperature distribution of the substrate.

14. The load-lock apparatus according to claim 12, wherein the controller is configured to control the heat source to output heat such that a uniform temperature distribution is achieved within the substrate.

15. The load-lock apparatus of claim 12, wherein the temperature measuring device is disposed outside the load-lock chamber and measures the substrate temperature through a measurement window.

16. The load-lock apparatus of claim 12, wherein the heat source comprises a plurality of independently controllable heating regions.

17. The load-lock apparatus of claim 12, wherein the support member is made of quartz glass or sapphire glass.

18. The load-lock apparatus of claim 12, wherein the heat source is a lamp heater comprising a plurality of annular lamps of different diameters.

19. The load-lock apparatus of claim 12, wherein the movable part is configured to move in a vertical direction with respect to the fixed part.

20. The load-lock apparatus of claim 12, wherein the controller is configured to control the heat source to heat the substrate while the movable part is moving.
